(19) United States
(12) Patent Application Publication
(10) Pub. No.: US 2025/0351283 A1
(43) Pub. Date: Nov. 13, 2025

(54) Power Conversion System

(71) Applicant: Anker Innovations Technology Co., Ltd., Changsha (CN)

(72) Inventors: Anfu Zeng, Shenzhen (CN); Jianguo Luo, Shenzhen (CN); Yi Ouyang, Shenzhen (CN); Denghui Xuan, Shenzhen (CN)

(21) Appl. No.: 19/180,768

(22) Filed: Apr. 16, 2025

(30) Foreign Application Priority Data
Apr. 29, 2024 (CN) 202420923371.6

(51) Int. Cl. H05K 5/03; H02M 7/00; H05K 5/00; H05K 5/02; H05K 5/06

(52) U.S. Cl. CPC H05K 5/03; H02M 7/003; H05K 5/0018; H05K 5/0247; H05K 5/069

(57) ABSTRACT

Various features herein describe a power conversion system, comprising a case, a screen display assembly, and a light transmission assembly. The case comprises a control board and a surface cover. The screen display assembly may be mounted on the surface cover. The screen display assembly is electrically connected to the control board, and the light transmission assembly covers the screen display assembly and may be mounted on the surface cover. The screen display assembly comprises a radar and a display screen distributed on the surface cover. When disassembling and replacing, a user only needs to remove the light transmission assembly from the surface cover, so radar and/or the display screen can be directly disassembled and replaced, without disassembling the surface cover.

### CROSS-REFERENCE TO RELATED APPLICATION

The present application claims priority to CN application No. 202420923371.6, filed on Apr. 29, 2024, which is incorporated by reference by its entirety.

### TECHNICAL FIELD

The present application relates to the technical field of electronic devices, in particular to a power conversion system with a case (e.g., a cover).

### BACKGROUND

In existing electronic device applications, the replacement of internal components within a surface cover, such as a display screen and a human-sensing radar screen structures, is inevitably. Taking a common power conversion system (PCS) enclosure as an example, the current technical solution involves removing the cover from one side of the enclosure and then detaching the required components from the cover for replacement.

Generally, a user's PCS is mounted on a wall. For example, a PCS is connected and assembled with a battery pack and then fixed to the wall. When the surface cover of the PCS case is disassembled to replace the screen display structure, it is inconvenient to remove the PCS from the wall. Also, during the process of disassembling the case and the surface cover, the circuit components inside the PCS may be directly exposed and damaged, and the service life of the entire PCS may be affected. In addition, dismantling and then reassembling (e.g., re-locking) the surface cover may affect the overall airtightness of the PCS case and affect the waterproof function of the PCS case.

### SUMMARY

The present application provides a power conversion system, which can solve the problems that it is inconvenient to disassemble a conventional surface cover because electronic components are prone to damage and the waterproof effect is affected.

Various features herein describe a power conversion system, comprising a case, a screen display assembly, and a light transmission assembly. The case comprises a control board and a surface cover. The screen display assembly may be mounted on the surface cover. The screen display assembly is electrically connected to the control board, and the light transmission assembly covers the screen display assembly and may be mounted on the surface cover. The screen display assembly comprises a radar and a display screen distributed on the surface cover. When disassembling and replacing, a user only needs to remove the light transmission assembly from the surface cover, so radar and/or the display screen can be directly disassembled and replaced, without disassembling the surface cover.

Based on the power conversion system in the example of the present application, when disassembling and replacing, a user only needs to open the light transmission assembly on the surface cover, and then replace the radar and/or the display screen in the screen display assembly according to actual needs, without disassembling the surface cover. Therefore, circuit components inside the PCS case will not be affected, and the subsequent waterproof effect will also not be affected.

In some examples, the radar includes a radar body and a sealing cover, the radar body is connected to the surface cover and connected to the control board via the first wire harness, and the sealing cover is detachably mounted on the surface cover and covers the radar body.

Based on the above examples, the radar body is sealed and protected, to prevent external air and water from entering the case through the place where the wire harness of the radar body passes through the surface cover.

In some examples, a first wire hole is formed on the sealing cover, a waterproof plug is embedded in the first wire hole, and a channel that allows the second wire harness to pass through is formed in the waterproof plug.

Based on the above examples, the waterproof plug is provided at the position where the display screen passes through the sealing cover, which can prevent water and air from entering the sealing cover and further ensure the dustproof and waterproof level.

In some examples, the screen display assembly further includes a light strip, and the light strip is connected to the radar through a third wire harness; or the second wire harness includes one first terminal and two second terminals, the first terminal is connected to the radar, and the two second terminals are connected to the light strip and the display screen respectively. Based on the above examples, the light strip not only adds a decorative effect for the screen display assembly to improve overall aesthetics, but also can adjust its brightness and color as needed to create different atmospheres. By designing the wire harness connection, the light strip and display screen components can be easily added or replaced.

In some examples, a portion of the side of the surface cover facing the screen display module is recessed inwards to form a mounting groove, the screen display assembly is arranged at a bottom of the mounting groove, and when the light transmission assembly is mounted on the surface cover, the side of the light transmission assembly facing away from the surface cover is flush with an opening of the mounting groove.

Based on the above example, the side of the entire surface cover facing the screen display assembly is a flat surface, and the screen display assembly does not protrude from the surface cover, thereby achieving a function of preventing accidental contact and ensuring overall aesthetics.

In some examples, a display area is provided on the side of the surface cover facing the screen display assembly, the display area transitions to the bottom of the mounting groove through a slope surface, and the light strip is arranged on the side of the groove bottom near the slope surface to illuminate the display area; and/or the light strip has multiple working modes, and when the light strip is in different working modes, the light transmission assembly shows different light output effects.

Based on the above examples, the light strip can illuminate the display area to highlight articles to be displayed in the display area. On the other hand, the light transmission assembly shows different light output effects, which not only meets the requirements of diverse and aesthetic light, but also can inform the user of the state of the power conversion system according to different light.

In some examples, the light strip includes a segment of continuous light components or a plurality of light components spaced apart, the light strip includes a shell and a light strip body, the shell is formed with a mounting chamber, the shell is detachably connected to the surface cover, and the light strip body is fitted into the mounting chamber.

Based on the above examples, the user is provided with more mounting options and more lighting options, and the light strip body is mounted in the shell, which can provide certain protecting and limiting effects on the light strip body.

In some examples, the light transmission assembly includes a back plate, the back plate is detachably mounted on the surface cover, and the display screen is detachably mounted on the back plate.

Based on the above examples, the light transmission assembly, the surface cover, and the display screen can be quickly disassembled.

In some examples, the back plate is provided with a first notch, and the display screen is correspondingly arranged in the first notch; and/or the back plate is further provided with a second notch, and the radar is correspondingly arranged in the second notch.

Based on the above examples, the first notch facilitates better display of the display screen through the light transmission assembly, and the second notch can reduce the shielding effect of the back plate on the radar.

In some examples, the light transmission assembly further includes a transparent protective layer; the transparent protective layer, the back plate, and the screen display assembly are distributed sequentially. An adhesive layer is provided between the transparent protective layer and the back plate to connect the transparent protective layer and the back plate.

Based on the above examples, the transparent protective layer does not affect the display of the screen display assembly, can provide additional protection for the screen display assembly, and can effectively prevent the screen display assembly from physical damage such as scratch and collision. Meanwhile, the transparent protective layer can resist the erosion of chemicals and stains and keep the screen display module clean and intact.

The power conversion system based on the examples of the present application includes a case, a screen display assembly, and a light transmission assembly, where the case has a surface cover, the screen display assembly is located outside the case and detachably mounted on the surface cover, and the light transmission assembly covers the screen display assembly to achieve a light transmission function, In addition, the light transmission assembly is detachably mounted on the surface cover, so when disassembling and replacing, the user only needs to remove the light transmission assembly from the surface cover. The screen display assembly includes radar and a display screen distributed on the surface cover, so the radar and/or the display screen can be directly disassembled and replaced according to actual needs, without disassembling the surface cover. In this way, circuit components inside the case will not be affected, and the waterproof effect will also not be affected.

### BRIEF DESCRIPTION OF THE DRAWINGS

To describe the technical solutions in the present application more clearly, the following briefly introduces the accompanying drawings required for describing the present application. Apparently, the accompanying drawings in the following description show only some examples of the present application, and those skilled in the art can derive other drawings from the accompanying drawings without any creative efforts.

FIG. 1 is an exploded structural diagram of a surface cover of a power conversion system provided in an example of the present application;

FIG. 2 is an enlarged schematic diagram of a structure at part A in FIG. 1;

FIG. 3 is an exploded diagram of a screen display assembly and a back plate provided in an example of the present application;

FIG. 4 is a schematic structural diagram of the surface cover and a light transmission assembly provided in an example of the present application in a mounting state;

FIG. 5 is a schematic structural diagram of the power conversion system provided in an example of the present application in a mounting state; and

FIG. 6 is an exploded structural diagram of the power conversion system provided in an example of the present application.

Reference numerals: 1. Case; 11. Base; 12. Decorative cover plate; 2. Surface cover; 2a. Mounting groove; 2b. Display area; 2c. Slope surface; 3. Screen display module; 31. Human detection radar; 311. Radar; 312. Sealing cover; 32. Display screen; 321. Mounting seat; 322. Display screen; 33. Light strip; 331. Shell; 332. Light strip; 4. Light transmission module; 41. Back plate; 41a. First notch; 41b. Second notch; 42. Transparent protective layer.

### DETAILED DESCRIPTION

In order to make the objectives, technical solutions, and advantages of the present application clearer, the following further describes the present application in detail in conjunction with the accompanying drawings and examples. It should be understood that the specific examples described herein are merely used for explaining the present application, but are not used for limiting the present application.

In the related art, it is inconvenient to disassemble a conventional surface cover from a case of a power conversion system case, electronic components inside the case are prone to damage and the waterproof function of the case is affected.

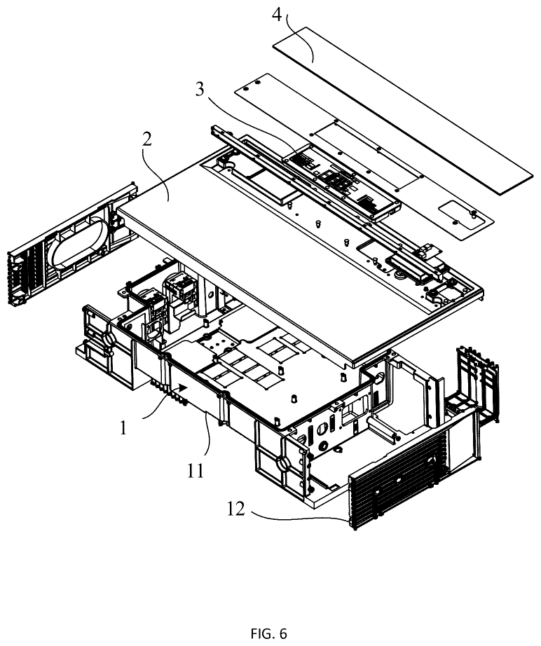

In order to solve the above technical problems, the present application provides a power conversion system, which can be applied in an energy storage system and connected between a battery system and a power grid to achieve bidirectional conversion of electrical energy. Specifically, the power conversion system can convert direct current of a battery into alternating current, which is then transmitted to the power grid or used by an alternating current load. Also or alternatively, the power conversion system can rectify alternating current of the power grid into direct current, which is then charged to a battery. As shown in FIG. 6, the power conversion system includes a case 1, a screen display module 3 (e.g., a screen display assembly), and a light transmission module 4 (e.g., a light transmission assembly). The power conversion system may further comprise one or more transformers, regulators, rectifiers, and other suitable electrical components for converting power.

The case 1 includes a base 11 and cover plates 12 located on two sides. The cover plates may be decorative. The cover plates 12 on the two sides are detachably mounted on the base 11 by, for example, bolt connection, fastener connection, etc. The base 11 and the cover plates 12 enclose and form an accommodating chamber, and a control board is provided in the accommodating chamber. The control board is mounted on the base 11. The case 1 has a surface cover 2. The surface cover 2 can be detachably mounted above the base 11 by, for example, bolt connection, fastener connection, etc., and seals the accommodating chamber to ensure the overall sealing effect of the accommodating chamber.

The screen display module 3 is located outside the case 1 and outside the accommodating chamber, and can be detachably mounted on the surface cover 2 by, for example, screw connection, fastener connection, or insertion. The screen display module 3 includes a human detection radar 31 and a display screen 32 spaced apart on the surface cover 2. The human detection radar 31 is connected to the control board in the case 1 through a first wire harness, and the display screen 32 is connected to the human detection radar 31 through a second wire harness. The control board extends wiring through the surface cover 2 to connect to the human detection radar 31, and the display screen 32 extends wiring to connect to the human detection radar 31. As such, the display screen 32 does not need to be connected to the control board in the case 1, reducing external-to-internal contact points and making it more convenient to replace the light strip 33 and/or the display screen 32.

The display screen 32 and the human detection radar 31 are staggered and do not interfere with each other. In order to better display the content on the display screen 32, the display screen 32 is generally arranged below the middle of the light transmission module 4.

The light transmission module 4 covers the screen display module 3. The light transmission module 4 can be made of a transparent material such as glass or a plastic board, such that light can be transmitted to the screen display module 3 by the light transmission module 4, or transmitted to the light transmission module 4 by the screen display module 3. The light transmission module 4 can be detachably mounted on the surface cover 2 by screw connection or fastener connection.

In an example of the present application, the screen display module 3 is located outside the case 1 and detachably mounted on the surface cover 2, while the light transmission module 4 covers the screen display module 3 to achieve a light transmission function. Meanwhile, the light transmission module 4 is detachably mounted on the surface cover 2. To replace or repair the human detection radar 31 and/or the display screen 32, a user only needs to remove the light transmission module 4 from the surface cover 2, and then replace the human detection radar 31 and/or the display screen 32 in the screen display module 3 without separating the surface cover 2 from the case 1. Therefore, circuit components inside the case 1 will not be affected, and the waterproof function of the case 1 will also not be affected.

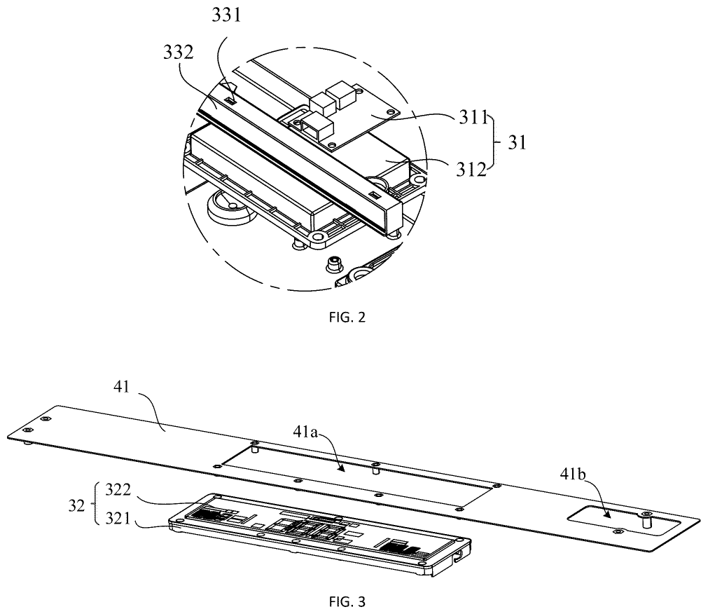

In order to further reduce the exchange contact inside and outside the case 1, as shown in FIG. 2, the human detection radar 31 includes a radar body 311 and a sealing cover 312, the radar body 311 is connected to the surface cover 2 and connected to the control board in the case 1 through the first wire harness, and the sealing cover 312 is detachably mounted on the surface cover 2 and completely covers the radar body 311 to ensure a good sealing effect.

Because the first wire harness, which connects the human detection radar 31 and the control board, passes through the surface cover 2, a wire hole is reserved and located on the surface cover 2 to allow the first wire harness to pass through. As such, there is a gap between the first wire harness and the wall of the wire hole, which affects the sealing of the case 1. Therefore, the sealing cover 312 is provided to ensure a certain level of scaling.

On the other hand, the radar body 311 may be vulnerable and susceptible to external environmental interference, such as water, dust, and light, so the sealing cover 312 can provide some protection for the radar body. In order to achieve convenient disassembly, the sealing cover 312 can be detachably mounted on the surface cover 2 by fastener connection, screw connection, etc.

On the basis of the previous example, a first wire hole is formed on the sealing cover 312, a waterproof plug is embedded in the first wire hole, and a channel that allows the second wire harness to pass through is formed in the waterproof plug.

Because the display screen 32 is connected to the human detection radar 31 through the second wire harness, the second wire harness passes through the sealing cover 312 via the first wire hole. As such, there is still a certain gap between the inner wall of the first wire hole and the second wire harness, and water and dust may still enter the sealing cover 312 to damage the radar body 311. Therefore, the waterproof plug is embedded in the first wire hole, and the channel that allows the second wire harness to pass through is formed in the waterproof plug.

The waterproof plug may be an elastic rubber plug, such as a rubber waterproof plug or a silicone waterproof plug. After the waterproof plug is squeezed and deformed, the channel therein can be tightly attached to the second wire harness. The waterproof plug can also be attached to the inner wall of the first wire hole, which can maximize the sealing effect of the sealing cover 312.

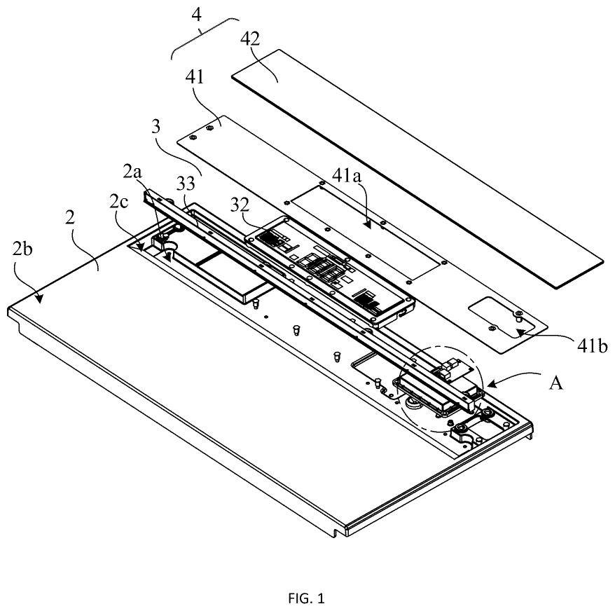

With reference to FIG. 1, the screen display module 3 further includes a light source such as a light strip 33. The light strip 33 is located below the light transmission module 4 and detachably connected to the surface cover 2 by fasteners such as screws, and the light strip 33 extends along a length direction of the surface cover 2. The display screen 32 and the human detection radar 31 are staggered and do not interfere with each other. The light strip 33 not only adds a decorative effect for the screen display module 3 to improve overall aesthetics, but also can adjust its brightness and color as needed to create different atmospheres. When the human detection radar 31 senses a human activity, the light strip can automatically light up or change its color, thereby providing visual feedback to the user and enhancing the interaction experience between the user and the device.

Parameters of the light strip 33, such as brightness and color, can be personalized by the control panel to meet the requirements of different users or scenarios. Meanwhile, combined with the function of the human detection radar 31, when no person approaches, the light strip 33 can automatically reduce its brightness or turn off to achieve an energy-saving effect.

The light strip 33 is connected to the human detection radar 31 through a third wire harness. The third wire harness enables the human detection radar 31 to supply power to the light strip 33. The third wire harness can also play a role in signal transmission. The third wire harness is designed specifically for power supply and signal transmission of the light strip 33, such that the connection between the light strip 33 and the human detection radar 31 is independent of the display screen 32, which reduces the possibility of mutual interference. When the light strip 33 is replaced or repaired, only the third wire harness needs to be handled without affecting the connection of other components.

In some examples, the second wire harness includes one first terminal and two second terminals, the first terminal is connected to the human detection radar 31, and the two second terminals are connected to the light strip 33 and the display screen 32 respectively. By optimizing the design of wire harnesses, the quantity of wire harnesses is reduced, thereby reducing manufacturing costs.

Regardless of the above connections, both the second wire harness and the third wire harness can pass through the waterproof plug, which can effectively improve the sealing effect.

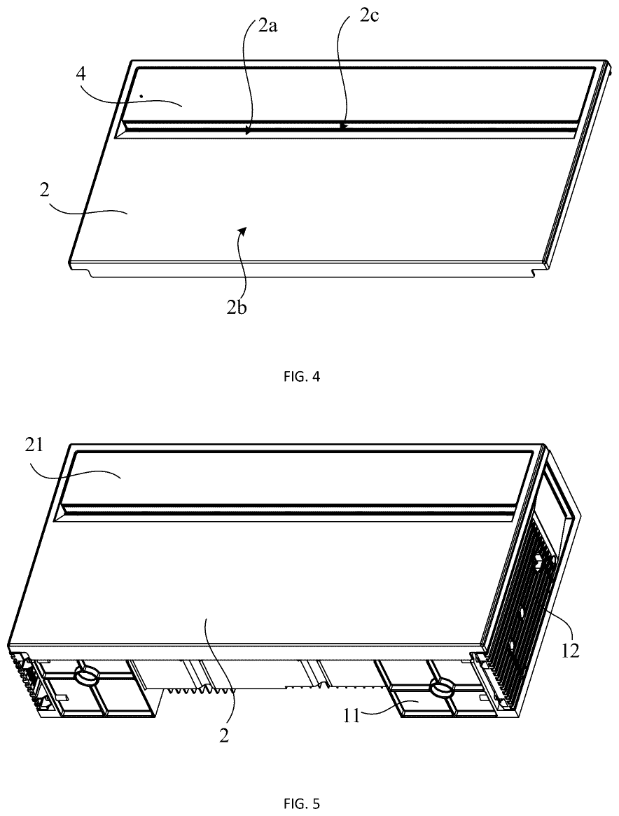

With reference to FIG. 1 and FIG. 4, a portion of the side of the surface cover 2 facing the screen display module 3 is recessed inwards to form a mounting groove 2a, and the screen display module 3 is arranged at a bottom of the mounting groove 2a. The shape of the mounting groove 2a is not limited and may be square, spherical, or conical. The mounting groove 2a provides a mounting space for the screen display module 3 and the light transmission module 4. When the light transmission module 4 is mounted on the surface cover 2, the side of the light transmission module 4 facing away from the surface cover 2 is flush with an opening of the mounting groove 2a.

As such, the side of the light transmission module 4 that is flush with the opening of the mounting groove 2a is also flush with the remaining non-recessed area of the surface cover 2, making the entire surface cover 2 neat. The light transmission module 4 does not protrude relative to the surface cover 2, which also reduces the risk of injury to some extent.

With continued reference to FIG. 4, specifically, a display area 2b is provided on the side of the surface cover 2 facing the screen display module 3. The display area 2b can be printed or engraved with promotional slogans or some signs on its surface. The display area 2b transitions to the bottom of the mounting groove 2a through a slope surface 2c, and the light strip 33 is arranged on the side of the groove bottom near the slope surface 2c to illuminate the display area 2b.

As shown in FIG. 1, the slope surface 2c may be a side wall of the mounting groove 2a and connects its opening and bottom. In the presence of the slope surface 2c, the area of the opening is greater than that of the groove bottom. Light emitted by the light strip 33 illuminates the display area 2b through the slope surface 2c, making the promotional slogans or some signs there more prominent, improving the display effect and enhancing the overall aesthetics of the product.

In some examples, the light strip 33 has multiple working modes. When the light strip 33 is in different working modes, the light transmission module 4 shows different light output effects.

The working modes can be set according to user selection. For example, when the power of the entire power conversion system is sufficient, the light strip 33 shows green light. When the power of the power conversion system is insufficient, the light strip 33 may show a red light. When a high temperature occurs inside the case 1, the light strip 33 can emit a red and green alternating light. The specific connection relationship is generally electrical connection, which will not be explained further here.

Specifically, the light strip 33 may be provided in at least one segment, or in multiple segments with the same or different light output effects to indicate that the entire power conversion system is in different working states. When the light strip 33 is in one segment, its maximum length can be the length of tempered glass 42.

With reference to FIG. 2, the light strip 33 includes a shell 331 and a light strip body 332, the shell 331 is formed with a mounting chamber, the shell 331 is detachably connected to the surface cover 2, and the light strip body 332 is fitted into the mounting chamber.

The light strip 332 may be generally a flexible strip structure that is prone to deformation. Therefore, in order to facilitate good light output effect, in an examples of the present application, the light strip body 332 is mounted in the mounting chamber formed by the shell 331. The shell 331 may be made of metal or plastic, the light strip body 332 is provided with a bump, and the shell 331 is provided with an adapted clamping groove. The bump and the clamping groove achieve the fitting of the light strip body 332 and the shell 331. The shell 331 is detachably fixed to the surface cover 2 by fasteners or screws, which facilitates subsequent disassembly.

Further, the light transmission module 4 includes a back plate 41, the back plate 41 is detachably mounted on the surface cover 2, and the display screen 32 is detachably mounted on the back plate 41 and located between the back plate 41 and the surface cover 2.

The back plate 41 provides a mounting position for the display screen 32, and the display screen 32 can be detachably mounted on the back plate 41 by fastener connection, screw connection, or bolt connection. The back plate 41 can be detachably mounted on the surface cover 2 by fastener connection, screw connection, or bolt connection, which is in the same way as that for the display screen 32. In the examples of the present application, a plurality of second pressure riveting screw columns (not marked) are further provided on the back plate 41, pass through the surface cover 2 and are connected to corresponding screws, to achieve the detachable connection between the back plate 41 and the surface cover 2.

Further, the back plate 41 is provided with a first notch 41a, the display screen 32 is correspondingly arranged in the first notch 41a, and the shape and size of the first notch 41a can match those of the display screen 32.

As shown in FIG. 3, the display screen 32 includes a mounting seat 321 and a display screen body 322 connected to each other, and the display screen body 322 is fitted into the first notch 41. By the first notch 41, the image displayed by the display screen body 322 can be directly displayed, such that the back plate 41 does not affect the quality of the image displayed by the display screen body 322.

The mounting seat 321 mainly supports the display screen body 322 and is located between the back plate 41 and the surface cover 2, and the mounting seat 321 is formed with holes that allow first pressure riveting screw columns to pass through.

The back plate 41 is further provided with a second notch 41b, the second notch is spaced apart from the first notch 41a, and the human detection radar 31 can be correspondingly arranged in the second notch 41b.

The back plate 41 has a certain shielding effect, especially when the back plate 41 is made of metal, so the second notch 41b can be formed on the back plate 41. Electromagnetic waves emitted or received by the human detection radar 31 pass through the second notch 41b. Therefore, the second notch 41b greatly reduces the impact of the back plate 41 on the human detection radar 31.

The shapes of the first notch 41a and the second notch 41b are not limited and may be circular, square, or bar-shaped.

With continued reference to FIG. 1, the light transmission module 4 further includes a transparent protective layer 42. The transparent protective layer 42, the back plate 41, and the screen display module 3 are arranged sequentially, and an adhesive layer is provided between the transparent protective layer 42 and the back plate 41 to connect the transparent protective layer 42 and the back plate 41.

The transparent protective layer 42 may be made of tempered glass or reinforced plastic, such as thermosetting resin or thermoplastic resin. In this example, in order to better exhibit the screen display module 3, tempered glass is used. The tempered glass is bonded to the back plate 41 by the adhesive layer. Generally speaking, in order to achieve better light output effect, the back plate 41 is made of metal, while the tempered glass 42 can ensure light transmission and has certain strength to prevent damage.

The adhesive layer may be a continuous adhesive area or a plurality of discontinuous adhesive areas. The adhesive layer may be transparent glue or other transparent adhesives, such as UV glue, without affecting the aesthetics of the entire light transmission module 4.

In some examples of the present application, after the tempered glass is bonded to the back plate 41 by the glass adhesive, in order to ensure the bonding strength between the two, they can be pressed for a period of time after being bonded together.

Specifically, for the sake of aesthetics, a plurality of first pressure riveting screw columns are provided on the side of the back plate 41 facing the surface cover 2. The first pressure riveting screw columns pass through the display screen 32 and are connected to corresponding screws to achieve a detachable connection. The pressure riveting screw columns are connected to the back plate 41 by riveting, which can ensure a smooth state of the side of the back plate 41 facing the tempered glass 42 and facilitate the connection between the back plate 41 and the tempered glass 42.

A mounting process of the case 1 and the surface cover 2 in the present application may be as follows: When assembling, the radar body 311, the sealing cover 312, the display screen 32, and the light strip 33 are first mounted on the surface cover 2 respectively, then the first wire harness is connected to the control board in the case 1, the surface cover 2 is locked with the base 11, and the decorative cover plates 12 on two sides are finally mounted.

As one of the ways, specifically: (1) The tempered glass 42 and the back plate 41 are bonded together by a glass adhesive and pressed for a period of time; (2) The display screen 32 is locked with screws to the pressure riveting screw columns riveted to the back of the back plate 41; (3) The light strip 33 is fixed to the surface cover 2 with screws; (4) The first wire harness led out from the control board is connected to the radar body 311, and the radar body 311 is locked to the surface cover 2 with screws; (5) After the light strip 33 and the second wire harness of the display screen 32 are connected to the radar body 311, power supply to the electronic components on the surface cover can be ensured. The sealing cover 312 is fixed to the surface cover 2 with screws, and the second wire harness passes through the waterproof rubber plug embedded in the sealing cover 312 to ensure the sealing effect; (6) Finally, the tempered glass 42 and the back plate 41 bonded into a whole are locked to the surface cover 2, to form a complete cover assembly.

The same or similar reference numerals in the accompanying drawings of the examples correspond to the same or similar components. In the description of the present application, it should be understood that if the terms such as “up”, “down”, “left”, and “right” indicate orientations or positional relationships based on the orientations or positional relationships shown in the accompanying drawings, it is only for the convenience of describing the present application and simplifying the description, and does not indicate or imply that the device or component referred to must have a specific orientation or be constructed and operated in a specific orientation. Therefore, the terms for describing the positional relationships in the accompanying drawings are only for illustrative description and cannot be understood as limitations of this patent. Those of ordinary skill in the art can understand the specific meanings of the above terms according to specific situations.

Described above are merely the preferred examples of the present application, which are not used for limiting the present application. Any modification, equivalent replacement and improvement, and the like made within the spirit and principle of the present application shall fall within the protection scope of the present application.

What is claimed is:

1. A power conversion system, comprising:
a case comprising a control board and a surface cover;
a screen display assembly mounted on the surface cover and electrically connected to the control board; and
a light transmission assembly mounted on the surface cover, wherein the light transmission assembly covers the screen display assembly, wherein:
the screen display assembly comprises a radar and a display screen,
the radar and the display screen are spaced apart on the surface cover,
the radar is connected to the control board via a first wire harness and configured to detect a human, and
the display screen is connected to the radar via a second wire harness.

2. The power conversion system according to claim 1, wherein:
the radar comprises a radar body and a sealing cover,
the radar body is connected to the surface cover and connected to the control board via the first wire harness, and
the sealing cover is mounted on the surface cover and covers the radar body.

3. The power conversion system according to claim 2, wherein:
a wire hole is formed on the sealing cover,
a waterproof plug is embedded in the wire hole, and
a channel that allows the second wire harness to pass through is formed in the waterproof plug.

4. The power conversion system according to claim 1, wherein:
the screen display assembly further comprises a light source, and
the light source is connected to the radar via a third wire harness or via the second wire harness.

5. The power conversion system according to claim 1, wherein:
a portion of a side of the surface cover facing the screen display assembly is recessed inwards to form a mounting groove,
the screen display assembly is arranged at a bottom of the mounting groove, and
a side of the light transmission assembly facing away from the surface cover is flush with an opening of the mounting groove.

6. The power conversion system according to claim 5, wherein:
a display area is provided on the side of the surface cover facing the screen display assembly,
the display area transitions to the bottom of the mounting groove through a slope surface, and
a light source is arranged on a side of the bottom of the mounting groove near the slope surface to illuminate the display area.

7. The power conversion system according to claim 4, wherein:
the light source has multiple working modes, and
based on the light source being in different working modes, the light transmission assembly is configured to show different light output effects.

8. The power conversion system according to claim 4, wherein the light source comprises a segment of continuous light components, or comprises a plurality of light components spaced apart, and
wherein each of the light components comprises a shell and a light strip, the shell is formed with a mounting chamber and is connected to the surface cover, and the light strip is fitted into the mounting chamber.

9. The power conversion system according to claim 1, wherein the light transmission assembly comprises a back plate mounted on the surface cover, and the display screen is mounted on the back plate.

10. The power conversion system according to claim 9, wherein the back plate is provided with a first notch, and the display screen assembly is arranged in the first notch, or the back plate is provided with a second notch, and the radar is arranged in the second notch.

11. The power conversion system according to claim 9, wherein:
the light transmission assembly further comprises a transparent protective layer and an adhesive layer, and
the adhesive layer is provided between the transparent protective layer and the back plate.

12. A power conversion system, comprising:
a control board;
a surface cover;
a screen display assembly mounted on the surface cover; and
a light transmission assembly mounted on the surface cover, wherein the light transmission assembly covers the screen display assembly, wherein:
the screen display assembly comprises a radar, a light source, and a display screen,
the radar is connected to the control board via a first wire harness,
the display screen is connected to the radar via a second wire harness, and
the radar is configured to detect a human and cause a change of the light source based on detection of the human.

13. The power conversion system of claim 12, wherein the display screen is not directly connected to the control board.

14. The power conversion system of claim 12, wherein the radar is connected to the light source via a third wire harness or the second wire harness.

15. The power conversion system of claim 12, wherein:
the radar comprises a radar body and a sealing cover,
the radar body is connected to the surface cover and connected to the control board via the first wire harness, and
the sealing cover is mounted on the surface cover and covers the radar body.

16. The power conversion system of claim 15, wherein:
a wire hole is formed on the sealing cover,
a waterproof plug is embedded in the wire hole, and
a channel that allows the second wire harness to pass through is formed in the waterproof plug.

17. The power conversion system of claim 12, wherein the light transmission assembly comprises a back plate mounted on the surface cover, and the display screen is mounted on the back plate.

18. The power conversion system of claim 17, wherein:
the light transmission assembly further comprises a transparent protective layer and an adhesive layer, and
the adhesive layer is provided between the transparent protective layer and the back plate.

19. The power conversion system of claim 12, wherein a portion of a side of the surface cover facing the screen display assembly is recessed inwards to form a mounting groove,
the screen display assembly is arranged at a bottom of the mounting groove, and
a side of the light transmission assembly facing away from the surface cover is flush with an opening of the mounting groove.

20. The power conversion system of claim 12, wherein each of the light transmission assembly and the display screen assembly is configured to detach from the surface cover.
